(19) United States
(12) Patent Application Publication
(10) Pub. No.: US 2025/0052877 A1
(43) Pub. Date: Feb. 13, 2025

(54) APPARATUS AND METHOD FOR DISTANCE MEASUREMENT USING ULTRASONIC WAVES

(71) Applicant: SAMSUNG ELECTRONICS CO., LTD., Suwon-si (KR)

(72) Inventors: Byung Hoon Ko, Suwon-si (KR); Jin Woo Choi, Suwon-si (KR); Seung Woo Noh, Suwon-si (KR); Sang Yun Park, Suwon-si (KR)

(73) Assignee: SAMSUNG ELECTRONICS CO., LTD., Suwon-si (KR)

(21) Appl. No.: 18/408,117

(22) Filed: Jan. 9, 2024

(30) Foreign Application Priority Data
Aug. 7, 2023 (KR) 10-2023-0102650

(51) Int. Cl. G01S 7/534; G01S 15/32

(52) U.S. Cl. CPC G01S 7/534; G01S 15/32

(57) ABSTRACT

An apparatus for distance measurement using ultrasonic waves may include: a memory configured to store an applied voltage profile that indicate voltages to be applied to a transducer at a plurality of different operational frequencies of transducer, a transducer including a transmitter configured to generate ultrasonic waves with a frequency modulated waveform, and a receiver configured to receive an echo signal reflected back from a measurement object; and a processor configured to control the transducer based on the applied voltage profile, and measure a distance to the measurement object based on the echo signal.

### CROSS-REFERENCE TO RELATED APPLICATION(S)

This application claims priority from Korean Patent Application No. 10-2023-0102650, filed on Aug. 7, 2023, in the Korean Intellectual Property Office, the disclosure of which is incorporated herein by reference in its entirety.

### BACKGROUND

### 1. Field

Apparatuses and methods consistent with example embodiments relate to distance measurement using ultrasonic waves, and more particularly to an ultrasonic sensor with wideband frequency characteristics.

### 2. Description of the Related Art

In distance measurement using ultrasonic waves, ultrasonic waves are generated to be incident on an object, and distance is measured by calculating the time taken for the ultrasonic signal to reflect back from the object. The distance measurement method using an ultrasonic sensor is performed with simple and relatively inexpensive equipment, and is mostly used indoors for measuring position of obstacles or distance to obstacles. The distance measurement method using the ultrasonic sensor may be performed in a relatively simple and inexpensive manner, but has a limited measurement distance and resolution. The speed and energy of ultrasonic waves of a typical ultrasonic sensor are changed depending on the properties of sound propagation in air or other medium, thereby causing an error in distance measurement.

### SUMMARY

Example embodiments address at least the above problems and/or disadvantages and other disadvantages not described above. Also, the example embodiments are not required to overcome the disadvantages described above, and may not overcome any of the problems described above.

According to an aspect of the present disclosure, an apparatus for distance measurement using ultrasonic waves may include: a memory configured to store an applied voltage profile that indicate voltages to be applied to a transducer at a plurality of different operational frequencies of the transducer; the transducer including a transmitter configured to generate ultrasonic waves with a frequency modulated waveform, and a receiver configured to receive an echo signal reflected back from a measurement object; and a processor configured to control the transducer based on the applied voltage profile, and measure a distance to the measurement object based on the echo signal.

The processor may be further configured to generate the applied voltage profile at a calibration time based on device characteristics of the transducer, to enable the echo signal received by the transducer to exhibit a target response characteristic in an operational frequency band of the transducer when the transducer is controlled based on the applied voltage profile.

The processor may be further configured to obtain calibration response characteristics in the operational frequency band by changing an applied voltage of the transducer, to generate the applied voltage profile by determining an applied voltage for each of the plurality of different operational frequencies of transducer based on the calibration response characteristics.

The target response characteristic may be set so that a constant amplitude response characteristic is obtained across the operational frequency band of the transducer.

The processor may be further configured to adjust the applied voltage profile based on at least one of a type of a device to which the apparatus is applied, and a mounting position of the transducer.

The apparatus may further include a Digital to Analog Converter (DAC) configured to convert a control signal of the processor into an analog signal and to transmit the analog signal to the transmitter.

The apparatus may further include an Analog to Digital Converter (ADC) configured to convert the echo signal of the receiver into a digital signal.

The apparatus may further include a Digital Signal Processor (DSP) configured to process the digital signal converted by the ADC, and to transmit the digital signal to the processor.

Each of the transmitter and the receiver of the transducer may be formed as an independent element.

At least one of the transmitter and the receiver of the transducer may include a piezoelectric element.

The transducer may include one or more channels, and each of the one or more channels may include the transmitter and the receiver which are integrated into a single package.

The apparatus may further include a communication device configured to transmit a processing result of the processor to an external device.

According to another aspect of the present disclosure, a method of distance measurement using ultrasonic waves, may include: by a processor, controlling a transducer based on an applied voltage profile that indicate voltages to be applied to the transducer at a plurality of different operational frequencies of transducer: by the transducer, generating ultrasonic waves with a frequency modulated waveform while the transducer is controlled based on the applied voltage profile: by the transducer, receiving an echo signal reflected back from a measurement object; and by the processor, measuring a distance to the measurement object based on the echo signal.

The method may further include generating the applied voltage profile at a calibration time based on device characteristics of the transducer, to enable the echo signal received by the transducer to exhibit a target response characteristic in an operational frequency band of the transducer when the transducer is controlled based on the applied voltage profile.

The generating of the applied voltage profile may include: obtaining calibration response characteristics in the operational frequency band of the transducer by changing an applied voltage; and generating the applied voltage profile by determining an applied voltage for each of the plurality of different operational frequencies of the transducer based on the calibration response characteristics.

The method may include, by a Digital to Analog Converter (DAC), converting a control signal for controlling the transducer into an analog signal and transmitting the analog signal to a transmitter of the transducer.

The method may further include, by an Analog to Digital Converter (ADC), converting the echo signal into a digital signal.

The method may further include by a Digital Signal Processor (DSP), processing the converted digital signal and transmitting the digital signal to the processor.

According to an aspect of the present disclosure, a device may include: a distance measurement apparatus configured to measure a distance to an object by using ultrasonic waves; and a processor configured to control the distance measurement apparatus based on distance information received from the distance measurement apparatus, wherein the distance measurement apparatus may be configured to: store an applied voltage profile that indicate voltages to be applied to a transducer at a plurality of different operational frequencies of the transducer; control the transducer to generate ultrasonic waves with a frequency modulated waveform, and receive an echo signal reflected back from the object; and measure the distance to the object by using the echo signal.

The device may be a Virtual Reality (VR) device, an Augmented Reality (AR) device, and an extended Reality (XR) device, a vehicle, or a robot.

### BRIEF DESCRIPTION OF THE DRAWINGS

The above and/or other aspects will be more apparent by describing certain example embodiments, with reference to the accompanying drawings, in which:

FIGS. 1A, 1B, and 1C are block diagrams illustrating an apparatus for distance measurement using ultrasonic waves according to embodiments of the present disclosure;

FIG. 2 is a diagram explaining an example of distance calculation using ultrasonic waves:

FIG. 3 is a diagram explaining an applied voltage profile and frequency response characteristics according to an embodiment of the present disclosure:

FIG. 4 is a diagram explaining an example of generating an applied voltage profile:

FIG. 5 is a flowchart illustrating a method of distance measurement using ultrasonic waves according to an embodiment of the present disclosure:

FIG. 6 is a flowchart illustrating a method of generating an applied voltage profile according to an embodiment of the present disclosure:

FIG. 7 is a block diagram illustrating a device including an apparatus for distance measurement according to an embodiment of the present disclosure:

FIGS. 8A, 8B, and 8C are diagrams illustrating examples of devices to which an apparatus for distance measurement using ultrasonic waves is applied.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

It will be understood that, although the terms, such as “first,” “second,” etc., may be used herein to describe various elements, these elements should not be limited by these terms. These terms are only used to distinguish one element from another. Any references to singular may include plural unless expressly stated otherwise. In addition, unless explicitly described to the contrary, an expression such as “comprising” or “including” will be understood to imply the inclusion of stated elements but not the exclusion of any other elements. Also, the terms, such as “unit” or “module,” etc., should be understood as a unit that performs at least one function or operation and that may be embodied as hardware, software, or a combination thereof.

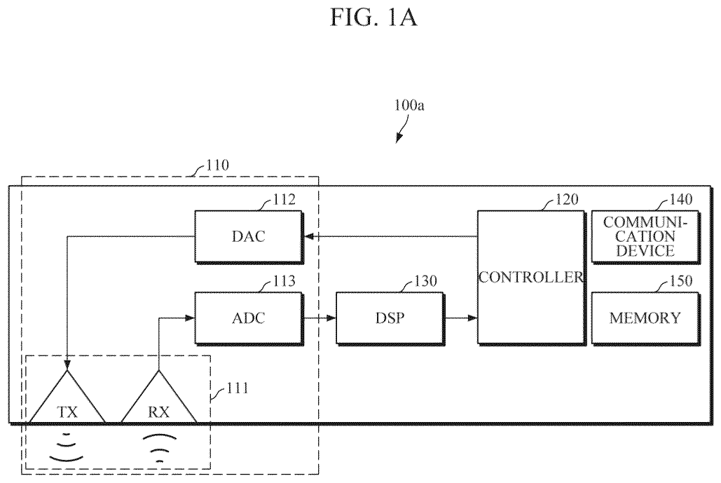

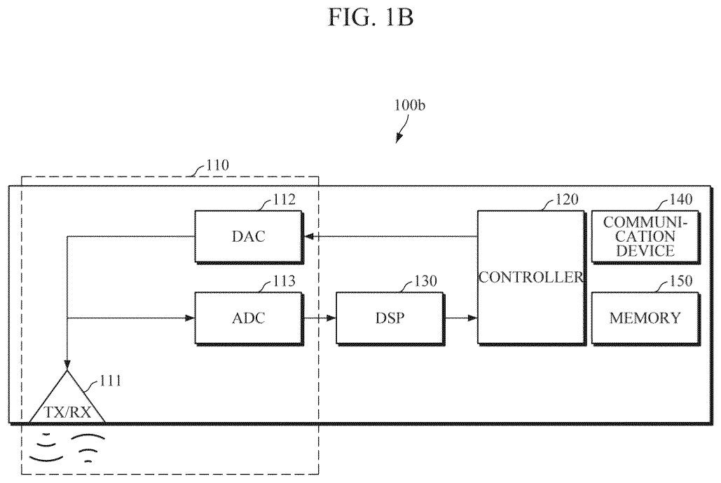

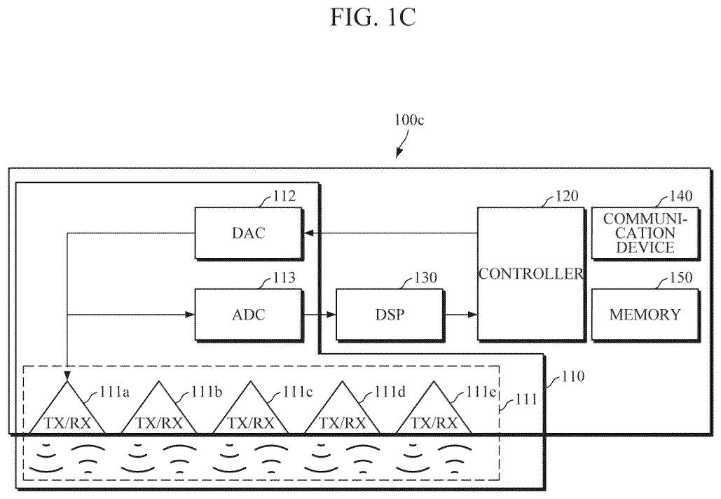

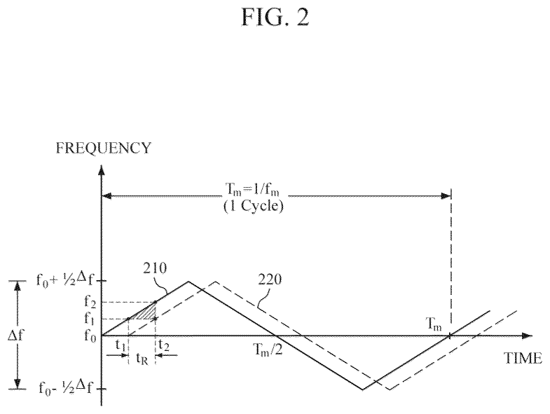

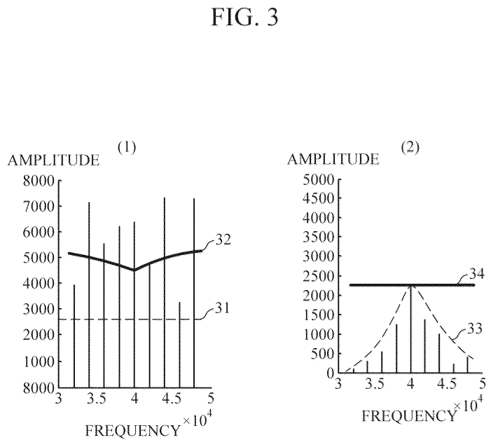

FIGS. 1A to 1C are block diagrams illustrating an apparatus for distance measurement using ultrasonic waves according to embodiments of the present disclosure. FIG. 2 is a diagram explaining an example of distance calculation using ultrasonic waves. FIG. 3 is a diagram explaining an applied voltage profile and frequency response characteristics according to an embodiment of the present disclosure.

Referring to FIGS. 1A to 1C, apparatuses 100a, 100b, and 100c for distance measurement using ultrasonic waves may include an ultrasonic sensor 110, a controller (e.g., a processor) 120, a Digital Signal Processor (DSP) 130, a communication device (e.g., a communication interface) 140, and a memory 150. The respective components may be implemented in the form of hardware or software or implemented as a combination thereof. The DSP 130 may be included in the controller 120.

The ultrasonic sensor 110 may include a transducer 111, a Digital-to-Analog Converter (DAC) 112, and an Analog-to-Digital Converter (ADC).

The transducer 111 includes a transmitter TX configured to generate ultrasonic waves with a frequency modulated waveform and to emit the ultrasonic waves toward a measurement object, and a receiver RX configured to receive an echo signal reflected back from the measurement object. An available frequency band (i.e., operational frequency band) of the transducer 111 may be determined based on interaction with the measurement object and distance measurement accuracy, and may be provided as a wide frequency band so that a distance may be measured with improved accuracy and high reliability.

The transmitter TX and the receiver RX may be piezoelectric transducers. As illustrated in FIG. 1A, the transmitter TX and the receiver RX may be formed on separate chips or packages, and the combination of the transmitter TX and the receiver RX operates as the transducer 111. Referring to FIG. 1B, a pair of the transmitter TX and the receiver RX may be integrated into a single transducer 111 to form a single channel. Referring to FIG. 1C, a plurality of pairs of the transmitters TX and the receivers RX may be integrated into a single package of the transducer 111 to form multiple channels 111a, 111b, 111c, 111d, and Ille. In this case, the number of channels is not limited thereto. While FIG. 1C illustrates an example in which the transmitter TX and the receiver RX are integrated into one package, the transmitter TX and the receiver RX are not limited thereto, and may be independently implemented as multiple channels.

In response to a control signal of the controller 120, the transmitter TX generates ultrasonic waves and emits the ultrasonic waves toward the measurement object. The DAC 112 may convert a digital signal generated by the controller 120 into an analog signal, and may transmit the analog signal through the transmitter TX. The receiver RX may receive an echo signal reflected back from the measurement object, and the ADC 113 may convert the echo signal in an analog signal format into a digital signal, and may transmit the digital signal to the controller 120. The digital signal converted by the ADC 113 may be processed by the DSP 130, to be transmitted to the controller 120. The DSP 130 may emphasize or remove a desired frequency band by performing, for example, digital filtering on the digital signal converted by the ADC 113. The echo signal, received by the receiver RX, may be mixed with ambient noise, such that for accurate distance measurement or object detection, a desired signal may be isolated or removed by the DSP 130.

By controlling the ultrasonic sensor 110 and analyzing a signal transmitted from the ultrasonic sensor 110 through the ADC 113 and the DSP 130, the controller 120 may perform operations such as calculating distance to the measurement object or detecting an object, and the like.

The controller 120 may control the ultrasonic sensor 110 by setting an operation cycle, sensitivity, measurement method, applied voltage, and the like of the ultrasonic sensor 110. In addition, in the case where the transducer 111 has multiple channels as illustrated in FIG. 1C, the controller 120 may select a channel to operate for distance measurement and object detection in a desired direction, and the like.

The controller 120 may set a voltage to be applied to the transducer 111 for each frequency in an operational frequency band of the transducer 111, by reference to an applied voltage profile stored in the memory 150. The applied voltage profile specifies the applied voltage corresponding to each frequency so that a response characteristic of the receiver RX exhibits a target response characteristic in the operational frequency band of the transmitter TX. The target response characteristic of a received echo signal may exhibit a constant amplitude with a predetermined margin, within the operational frequency band of the transducer 111. The applied voltage profile is generated by calibration, and may be generated by reflecting device characteristics of the transducer 111, applied devices (e.g., Virtual Reality (VR) device, Augmented Reality (AR) device, Extended Reality (XR) device, vehicles, robots, etc.), mounting position of the transducer 111, types of components/materials at the mounting position, and the like.

Referring to FIG. 2, the controller 120 may generate a transmission signal 210 by applying frequency-modulated continuous waves (FMCW) to the transmitter TX using a frequency band Δf(f₀±Δf/2) and a cycle Tₘ during a continuous period of time, and may calculate distance by analyzing a received signal 220 received by the receiver RX. For example, assuming that a distance between the transducer 111 and a measurement object is L, a speed of sound in a medium is Vs, and time taken for the ultrasonic signal to reflect back from the measurement object is t_{R}, L=Vs×t_{R}/2.

Referring to FIG. 3, when a constant voltage 31 is applied in a common frequency band (3×10⁴≤f₀=4≤5×10⁴) used by the transducer 111 in graph (1), it can be seen from graph (2) that a frequency response characteristic 33 (e.g., an amplitude of the received signal 220) of the transducer 111 gradually decreases starting at f₀=4 as the frequency increase. Frequency response characteristics of the transmitter TX and the receiver RX are important for accurate distance measurement using wideband frequency ultrasonic waves, and response characteristics in an applied frequency band are required to have a constant target frequency response characteristic 34. To this end, in order to obtain constant frequency response characteristics of the transducer 111, an applied voltage profile is generated by defining an applied voltage 32 for each frequency in an operational frequency band, and a voltage may be applied according to the applied voltage profile.

Referring back to FIGS. 1A to 1C, the communication device 140 may support establishment of a direct (e.g., wired) communication channel and/or a wireless communication channel between the apparatus 100 for distance measurement and other electronic device, a server, or a sensor device within a network environment, and performing of communication via the established communication channel, by using various communication techniques. The communication device 140 may receive a request of another device and transmit the request to the controller 120, and may transmit a processing result (e.g., information about distance to the measurement object) of the controller 120 to another device.

The communication techniques may include Bluetooth communication, Bluetooth Low Energy (BLE) communication, Near Field Communication (NFC), WLAN communication, Zigbee communication, Infrared Data Association (IrDA) communication, Wi-Fi Direct (WFD) communication, Ultra-Wideband (UWB) communication, Ant+ communication, WIFI communication, Radio Frequency Identification (RFID) communication, 3G, 4G, and 5G communications, direct connection via an internal bus, and the like. However, the communication techniques are not limited to the listed examples.

The memory 150 may store instructions and/or data for controlling the overall operation of the apparatus 100 for distance measurement. The data may include basic information, such as a frequency band for controlling the ultrasonic sensor 110, the applied voltage profile, an operation cycle, sensitivity, measurement method, and the like. In addition, the memory 150 may include distance information generated by the controller 120. The memory 150 may include Random Access Memory (RAM), such as Dynamic Random Access Memory (DRAM), Static Random Access Memory (SRAM), etc., Read-Only Memory (ROM), flash memory, cache memory, virtual memory, etc., but is not limited not to the listed examples.

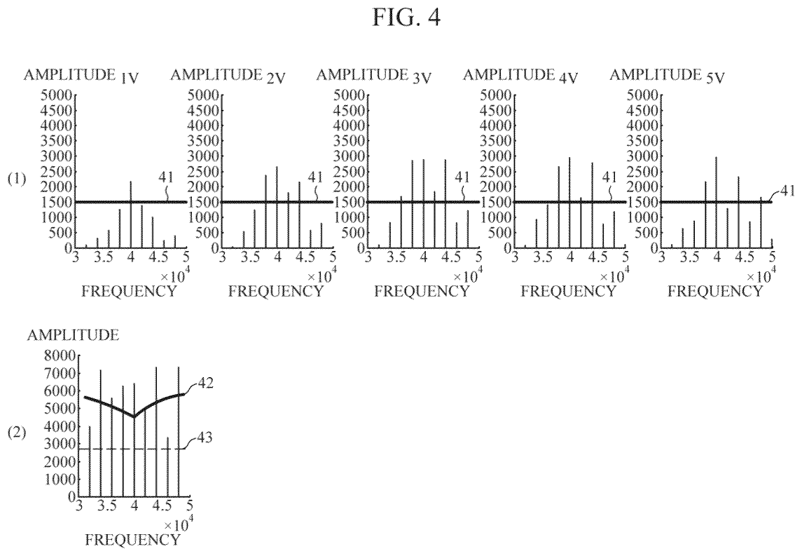

FIG. 4 is a diagram explaining an example of generating an applied voltage profile.

The controller 120 may perform calibration to generate an applied voltage profile based on device characteristics of the transducer 111. The calibration may be performed at the time of manufacture of the apparatus 100. In addition, when the apparatus 100 is applied to an external device using information about distance to an object, the controller 120 may perform calibration periodically or each time usage environment changes, such as in the case in which a mounting position of the ultrasonic sensor 110 changes or when a component/material at the mounting position changes, and the like. Alternatively, calibration may be performed once at the time of manufacture of the apparatus 100, and if the controller 120 later detects a change in usage environment or if usage environment is input by a user, the controller 120 may adjust or update the applied voltage profile, generated at the time of manufacture, according to the usage environment. In this case, adjustment criteria may be predefined in the form of a lookup table or mathematical function, or the controller may adjust or update the applied voltage profile by receiving an applied voltage to be adjusted from a user.

Referring to FIG. 4, as shown in graphs (1), the controller 120 may obtain calibration response characteristics for each applied voltage, by changing applied voltages 1V, 2V, 3V, 4V, 5V, . . . in an operational frequency band of the transducer 111. Then, the controller 120 may determine an applied voltage for each frequency so that a target response characteristic 41 may be exhibited.

For example, during calibration, amplitude characteristics of received (echo) signals are measured for applied voltages of 1V to 5V at a frequency of 4×10⁴ For a frequency at which all amplitude characteristics exceed a target response characteristic, an applied voltage of 1V or less may be determined. In addition, when applied voltages are 1V and 2V at a frequency of 3.5×10⁴, calibration amplitude characteristics are less than the target response characteristic, while the calibration amplitude characteristics are close to the target response characteristic. Thus, an applied voltage of about 3V to 4V may be determined at the frequency of 3.5×10⁴. In this manner, an applied voltage profile may be generated by determining an applied voltage 42 for each frequency in the entire frequency band of the transducer 111, as shown in graph (2). The applied voltage may be generated in the form of a lookup table or mathematical function and may be stored in the memory 150. Accordingly, it is possible to prevent reduction in accuracy of distance measurement, which may be reduced due to non-uniform frequency response characteristics when the same applied voltage 43 is generally used in the entire frequency band.

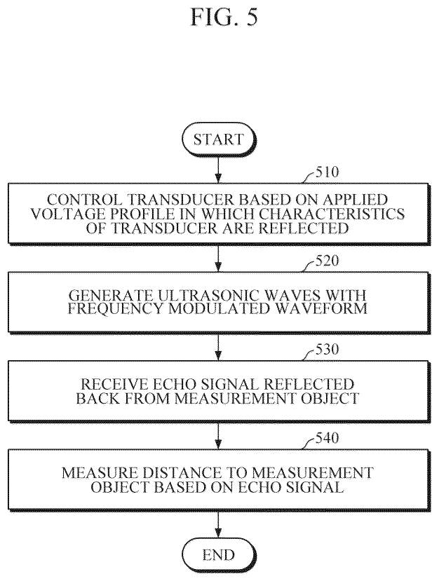

FIG. 5 is a flowchart illustrating a method of distance measurement using ultrasonic waves according to an embodiment of the present disclosure.

The method of FIG. 5 is an example of a method of distance measurement performed by the apparatus 100 for distance measurement of FIG. 1, and thus will be briefly described below.

First, the controller may control the transducer in operation 510 based on an applied voltage profile that is generated during calibration. The applied voltage profile may reflect the response characteristics of received (echo) signals of the transducer of the ultrasonic sensor. Specifically, the applied voltage profile may indicate specific voltages to be applied to the transducer at each of a plurality of different frequencies, enabling the transducer to receive signals having uniform or constant frequency response characteristics in a wide frequency band of the ultrasonic sensor. The applied voltage profile may be previously generated in the form of a mathematical function or lookup table that defines a relationship therebetween, and the like.

Then, the transmitter of the transducer may generate ultrasonic waves with a frequency modulated waveform based on the applied voltage, and may emit the ultrasonic waves toward a measurement object in operation 520.

Subsequently, the receiver of the transducer may receive an echo signal reflected back from the measurement object, and may transmit the echo signal to the controller in operation 530. In this case, the echo signal may be converted into a digital signal, and the converted digital signal may be processed to remove noise and the like, and then is transmitted to the controller.

Next, the controller may analyze the echo signal to measure a distance to the measurement object in operation 540. The distance may be obtained by multiplying a speed of sound in a medium by a value obtained by dividing in half a difference between sending time and receiving time.

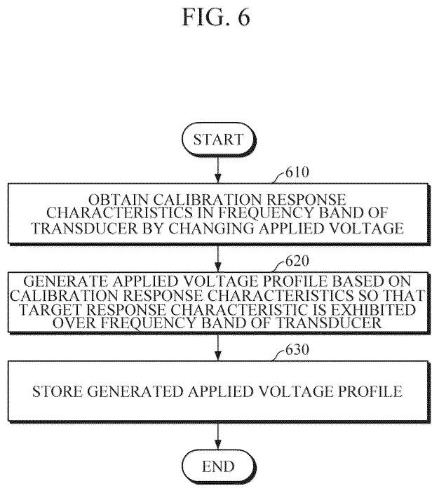

FIG. 6 is a flowchart illustrating a method of generating an applied voltage profile according to an embodiment of the present disclosure.

The method of FIG. 6 is an example of a method of generating an applied voltage profile which is performed by the apparatus 100 for distance measurement of FIG. 1, and thus will be briefly described below.

The apparatus 100 for distance measurement may obtain calibration response characteristics in an operational frequency band of the transducer in operation 610, may generate an applied voltage profile based on calibration response characteristics in operation 620 so that a target response characteristic is exhibited over the frequency band of the transducer, and may store the generated applied voltage profile in the memory in operation 630. As shown in graph (1) of FIG. 4, calibration response characteristics are obtained for each applied voltage by changing applied voltages in the operational frequency band, and an applied voltage profile may be generated based on the obtained calibration response characteristics by determining an applied voltage for each frequency as in the case where the applied voltage 42 gradually increases at frequencies on both sides of a frequency of 4×10⁴ in the frequency band, instead of using a constant applied voltage 43 over the entire frequency band as shown in graph (2). In this case, the applied voltage profile may be defined in the form of a lookup table or mathematical function.

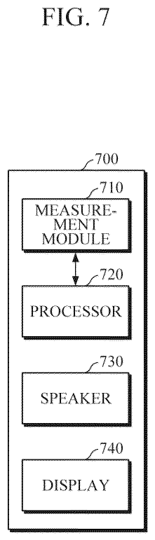

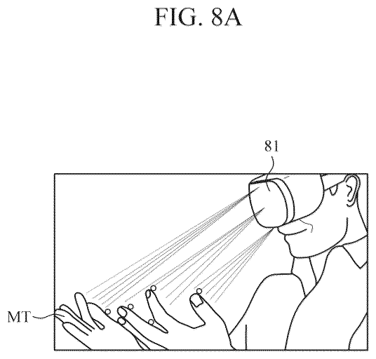

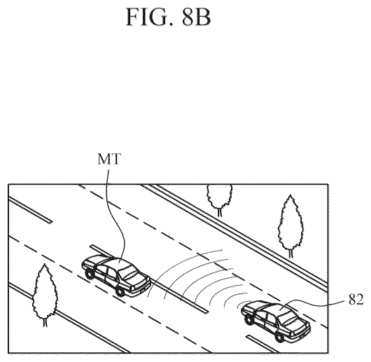

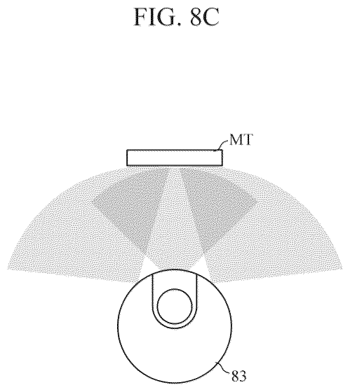

FIG. 7 is a block diagram illustrating a device including an apparatus for distance measurement according to an embodiment of the present disclosure. FIGS. 8A to 8C are diagrams illustrating examples of devices to which an apparatus for distance measurement using ultrasonic waves is applied.

Referring to FIG. 7, a device 700 includes a measurement module 710, a processor 720, a speaker 730, and a display 740. The measurement module 710 includes the components 110, 111, 112, 113, 120, 121, 130, 140, and 150 of the aforementioned apparatus 100 for distance measurement using ultrasonic waves. The components of the measurement module 710 may be formed integrally or separately and mounted in the device 700 in the form of hardware or software. The ultrasonic sensor 110 may be provided at an appropriate position by considering the purpose of distance measurement of the device 700, a type of the device 700, and the like.

The processor 720 may control the overall operation of the measurement module 710, and may perform various operations defined in the device 700 based on information about distance to an object (e.g., front obstacle) which is measured by the measurement module 710. For example, the processor 720 may provide information about distance to the object, object motion information, and the like in an audio or visual manner by using the speaker 730, the display 740, and the like. The display 740 may include a display screen or monitor, and a visual indicator such an LED. In addition, if a distance to the object falls within a predetermined range, the processor 720 may provide warning information, and may control other components of the device 700 to perform an avoidance action to move while avoiding an object, a stop action to stop moving, and the like.

Referring to FIGS. 8A to 8C, the device 700, to which the apparatus for distance measurement using ultrasonic waves is applied, may include various devices using distance measurement, such as a portable device 81 including a Virtual Reality (VR) device, an Augmented Reality (AR) device, and an extended Reality (XR) device, a vehicle 82, a mobile robot 83, and the like. The VR or AR device may display objects using depth information obtained through the measurement module 710. The vehicle 82 may determine distances from nearby vehicles 82 and may autonomously manage its driving to uphold safe distances, issuing warnings via the speaker 730 or the display 740 when the distance decreases below a preset threshold. Additionally, the mobile robot 83 can navigate within a specified area autonomously, averting collisions by utilizing distance measurements obtained from the measurement module 710. As illustrated herein, the devices 81, 82, and 83 may recognize a front object MT and/or measure a distance to the object, and may perform necessary operations by using the recognized/measured information, thereby providing AR, VR, and XR User Experience or functions such as autonomous driving and the like.

While not restricted thereto, an example embodiment can be embodied as computer-readable code on a computer-readable recording medium. The computer-readable recording medium is any data storage device that can store data that can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network-coupled computer systems so that the computer-readable code is stored and executed in a distributed fashion. Also, an example embodiment may be written as a computer program transmitted over a computer-readable transmission medium, such as a carrier wave, and received and implemented in general-use or special-purpose digital computers that execute the programs. Moreover, it is understood that in example embodiments, one or more units of the above-described apparatuses and devices can include circuitry, a processor, a microprocessor, etc., and may execute a computer program stored in a computer-readable medium.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An apparatus for distance measurement using ultrasonic waves, the apparatus comprising:
a memory configured to store an applied voltage profile that indicate voltages to be applied to a transducer at a plurality of different operational frequencies of the transducer;
the transducer comprising a transmitter configured to generate ultrasonic waves with a frequency modulated waveform, and a receiver configured to receive an echo signal reflected back from a measurement object; and
a processor configured to control the transducer based on the applied voltage profile, and measure a distance to the measurement object based on the echo signal.

2. The apparatus of claim 1, wherein the processor is further configured to generate the applied voltage profile at a calibration time based on device characteristics of the transducer, to enable the echo signal received by the transducer to exhibit a target response characteristic in an operational frequency band of the transducer when the transducer is controlled based on the applied voltage profile.

3. The apparatus of claim 2, wherein the processor is further configured to obtain calibration response characteristics in the operational frequency band by changing an applied voltage of the transducer, to generate the applied voltage profile by determining an applied voltage for each of the plurality of different operational frequencies of transducer based on the calibration response characteristics.

4. The apparatus of claim 2, wherein the target response characteristic is set so that a constant amplitude response characteristic is obtained across the operational frequency band of the transducer.

5. The apparatus of claim 1, wherein the processor is further configured to adjust the applied voltage profile based on at least one of a type of a device to which the apparatus is applied, and a mounting position of the transducer.

6. The apparatus of claim 1, further comprising a Digital to Analog Converter (DAC) configured to convert a control signal of the processor into an analog signal and to transmit the analog signal to the transmitter.

7. The apparatus of claim 1, further comprising an Analog to Digital Converter (ADC) configured to convert the echo signal of the receiver into a digital signal.

8. The apparatus of claim 7, further comprising a Digital Signal Processor (DSP) configured to process the digital signal converted by the ADC, and to transmit the digital signal to the processor.

9. The apparatus of claim 1, wherein each of the transmitter and the receiver of the transducer is formed as an independent element.

10. The apparatus of claim 1, wherein at least one of the transmitter and the receiver of the transducer comprises a piezoelectric element.

11. The apparatus of claim 1, wherein the transducer comprises one or more channels, and each of the one or more channels comprises the transmitter and the receiver which are integrated into a single package.

12. The apparatus of claim 1, further comprising a communication device configured to transmit a processing result of the processor to an external device.

13. A method of distance measurement using ultrasonic waves, the method comprising:
by a processor, controlling a transducer based on an applied voltage profile that indicate voltages to be applied to the transducer at a plurality of different operational frequencies of transducer;
by the transducer, generating ultrasonic waves with a frequency modulated waveform while the transducer is controlled based on the applied voltage profile;
by the transducer, receiving an echo signal reflected back from a measurement object; and
by the processor, measuring a distance to the measurement object based on the echo signal.

14. The method of claim 13, further comprising generating the applied voltage profile at a calibration time based on device characteristics of the transducer, to enable the echo signal received by the transducer to exhibit a target response characteristic in an operational frequency band of the transducer when the transducer is controlled based on the applied voltage profile.

15. The method of claim 14, wherein the generating of the applied voltage profile comprises:
obtaining calibration response characteristics in the operational frequency band of the transducer by changing an applied voltage; and
generating the applied voltage profile by determining an applied voltage for each of the plurality of different operational frequencies of the transducer based on the calibration response characteristics.

16. The method of claim 13, further comprising, by a Digital to Analog Converter (DAC), converting a control signal for controlling the transducer into an analog signal and transmitting the analog signal to a transmitter of the transducer.

17. The method of claim 13, further comprising, by an Analog to Digital Converter (ADC), converting the echo signal into a digital signal.

18. The method of claim 17, further comprising, by a Digital Signal Processor (DSP), processing the converted digital signal and transmitting the digital signal to the processor.

19. A device comprising:
a distance measurement apparatus configured to measure a distance to an object by using ultrasonic waves; and
a processor configured to control the distance measurement apparatus based on distance information received from the distance measurement apparatus,
wherein the distance measurement apparatus is configured to:
store an applied voltage profile that indicate voltages to be applied to a transducer at a plurality of different operational frequencies of the transducer;
control the transducer to generate ultrasonic waves with a frequency modulated waveform, and receive an echo signal reflected back from the object; and
measure the distance to the object by using the echo signal.

20. The device of claim 19, wherein the device is a Virtual Reality (VR) device, an Augmented Reality (AR) device, and an extended Reality (XR) device, a vehicle, or a robot.
